(19) United States
(12) Patent Application Publication
(10) Pub. No.: US 2004/0077115 A1
(43) Pub. Date: Apr. 22, 2004

(54) Performance of electronic and optoelectronic devices using a surfactant during epitaxial growth

(76) Inventors: Yong-Hang Zhang, Scottsdale, AZ (US); Yuri Sadofyev, Tempe, AZ (US); Shane Richard Johnson, Chandler, AZ (US)

Correspondence Address: GALLAGHER & KENNEDY, P. A., 2575 E. CAMELBACK RD. #1100, PHOENIX, AZ, 85016, US

(21) Appl. No.: 10/683,822

(22) Filed: Oct. 10, 2003

Related U.S. Application Data
(60) Provisional application No. 60/417,988, filed on Oct. 11, 2002.

(51) Int. Cl. H01L 21/00

(52) U.S. Cl. 438/47; 438/507

(57) ABSTRACT

A method of fabricating a semiconductor device, such as a high electron mobility transistor, a vertical cavity surface emitting laser, an edge emitting laser, a heterostructure bipolar transistor, a resonant tunneling diode, and the like, is disclosed that includes the steps of depositing a plurality of layers of semiconductor material including at least one active area with opposed major surfaces and a cladding layer adjacent each opposed major surface. In the disclosure, the semiconductor material is in an aluminum/gallium arsenide semiconductor system. At least one of the active area and the cladding layers are deposited at relatively low temperatures in the presence of a surfactant, such as antimony, indium, bismuth or thallium to produce greatly improved carrier mobility and surface morphology.

### CROSS-REFERENCE TO RELATED APPLICATION

This application claims priority from U.S. provisional application No. 60/417,988, filed Oct. 11, 2002.

### FIELD OF THE INVENTION

This invention relates to electronic and optoelectronic semiconductor devices and, more particularly, to improving the material quality of layers included in such devices.

### BACKGROUND OF THE INVENTION

Optoelectronic devices such as lasers, photo detectors, modulators, and the like, are often used in high-speed data communication systems. These optoelectronic devices are needed to operate at high frequencies with minimal heat generation, which negatively affects device lifetime and performance. One cause of heat generation in typical optoelectronic devices is due to a series resistance measured between electrical contacts which supply power to an active region. In a light-emitting device, for example, a high series resistance can decrease light emission which reduces the distance the light can propagate through a light guiding element such as an optical fiber. Another effect of a high series resistance is to decrease frequency performance, which limits the rate that information can be transferred. A high series resistance is partly caused by surface roughness and poor carrier mobility of a material layer included in the optoelectronic device wherein the series resistance increases with roughness and reduced carrier mobility.

The performance of electronic devices such as high electron mobility transistors, resonant tunneling diodes, and heterojunction bipolar transistors is also limited by interface morphology and electron mobility. High electron mobility transistors perform better with smooth interfaces near a conduction channel. The homogeneity of resonant tunneling diodes and heterojunction bipolar transistors is also sensitive to interface roughness.

One method to decrease the surface roughness and to improve electron mobility is to increase the deposition temperature of the layer. However, increased deposition temperatures may not be compatible with other layers included in the optoelectronic device and can cause other properties of the grown layer to degrade, such as layer composition through the preferential evaporation of one of the layer constituents. Thus, it is highly desirable to fabricate optoelectronic and electronic devices at a lower deposition temperature with an improved material quality and, consequently, to improved carrier mobility and surface morphology.

It would be highly advantageous, therefore, to remedy the foregoing and other deficiencies inherent in the prior art.

Accordingly, it is an object of the present invention to provide a new and improved semiconductor device and method of forming the device using a surfactant during epitaxial growth.

Another object of the invention is to provide a new and improved semiconductor device and method of forming the device in which deposition temperatures are reduced.

A further object of the invention is to provide a new and improved semiconductor device and method of forming the device with improved carrier mobility and surface morphology.

### SUMMARY OF THE INVENTION

The above problems and others are at least partially solved and the above purposes and others realized in a new and improved method of fabricating a semiconductor device including the steps of depositing multiple layers of semiconductor material on a supporting substrate to form the semiconductor device and depositing at least one layer of the multiple layers in the presence of a surfactant.

In a preferred embodiment the semiconductor device includes at least one of a high electron mobility transistor, a vertical cavity surface emitting laser, an edge emitting laser, a heterostructure bipolar transistor, a resonant tunneling diode, and the like. In a VCSEL, for example, the steps of depositing a plurality of layers of semiconductor material include at least one active area with opposed major surfaces and a cladding layer adjacent each opposed major surface. Further, in the preferred embodiment the semiconductor material is in an aluminum/gallium arsenide semiconductor system. At least one of the active area and the cladding layers are deposited at relatively low temperatures (approximately 580° C. to 720° C.) in the presence of a surfactant, such as antimony, indium, bismuth or thallium to produce greatly improved carrier mobility and surface morphology.

The above problems and others are at least partially solved and the above purposes and others realized in a new and improved semiconductor device including a plurality of layers of semiconductor material epitaxially grown one on another and at least one of the semiconductor layers including a surfactant (included during the growth of the semiconductor material) with the semiconductor material.

### BRIEF DESCRIPTION OF THE DRAWINGS

The foregoing and further and more specific objects and advantages of the invention will become readily apparent to those skilled in the art from the following detailed description taken in conjunction with the drawings in which:

FIG. 1 is a sectional view of a semiconductor laser device in accordance with the present invention;

FIG. 2 is a graph of surface roughness of an aluminum gallium arsenide (AlₓGaₗ₋ₓAs) layer deposited in accordance with the present invention;

FIG. 3 is a photoluminescence graph of a gallium arsenide (GaAs) quantum well structure deposited in accordance with the present invention; and

FIG. 4 is a graph of electron mobility of an aluminum gallium arsenide (AlₓGaₗ₋ₓAs) layer deposited in accordance with the present invention.

### DETAILED DESCRIPTION OF THE DRAWINGS

Turn now to FIG. 1 which illustrates a semiconductor laser device 5 (not necessarily complete, i.e. contacts and other features not affected by this invention have been omitted for simplicity of this description) with a wavelength of operation in accordance with the present invention. It will be understood that laser device 5 is shown to illustrate a method of fabricating a semiconductor device using a surfactant, in accordance with the present invention. As will be understood after a careful study of the detailed description below, the method of fabrication could be used to fabricate other semiconductor devices, such as high electron mobility transistors, vertical cavity surface emitting lasers, edge emitting lasers, heterostructure bipolar transistors, resonant tunneling diodes or the like, wherein it is desired to improve the electrical or interfacial properties of the device. Further, these semiconductor devices can include various semiconductor material systems, such as indium gallium arsenic nitride (InₓGaₗ₋ₓAs_{y}N_{l-y}), aluminum gallium arsenide phosphide (AₗₓGaₗ₋ₓAs_{y}P_{l-y}) or the like wherein x and y are numbers within a range from zero to one.

Further, it will be understood that while one laser device 5 is illustrated for simplicity, generally a plurality of devices are deposited or grown in blanket layers over an entire wafer so that a large number of devices are fabricated simultaneously. In a preferred embodiment, semiconductor laser device 5 is fabricated using a molecular beam epitaxy system. However, it will be understood that device 5 can be fabricated using a metal-organic chemical vapor deposition system, a chemical vapor deposition system, or another semiconductor deposition system.

Semiconductor laser device 5 includes a substrate 10 that includes semi-insulating gallium arsenide (GaAs) oriented in a (100) direction with a buffer layer 12 deposited thereon. A cladding region 14 is deposited on buffer layer 12. A light emitting region 16 is deposited between cladding region 14 and a second cladding region 22. In the preferred embodiment, cladding regions 14 and 22 are deposited in the presence of a surfactant, as will be discussed separately. Further, in the preferred embodiment, a capping layer 24 is deposited on cladding region 22.

It will be understood that substrate 10 can include other materials, such as indium phosphide, silicon, or the like, wherein the choice of substrate material generally depends on the desired application. Further it will be understood that substrate 10 can have various orientations and doping concentrations and that the use of a semi-insulating gallium arsenide substrate oriented in the (100) direction in this embodiment is for illustrative purposes only. One of the functions of buffer layer 12 is to provide a pristine surface on substrate 10 for subsequent layers deposited thereon. It will be understood, however, that buffer layer 12 is optional and is included in this embodiment for illustrative purposes.

Light emitting region 16 can include many different configurations to produce substantial light emission at a desired wavelength. For example, light emitting region 16 can include quantum dots or other quantum structures well known to those skilled in the art. In the preferred embodiment described here, the use of quantum wells is for illustrative purposes only.

Light emitting region 16 includes alternating layers of a barrier layer, designated 18 and an active region, designated 20. Barrier layers 18 in this example include aluminum gallium arsenide (AlₓGaₗ₋ₓAs), wherein x is a number within a range from zero to one, and active regions 20 include gallium arsenide (GaAs) quantum wells. The quantum wells used in this embodiment have a width approximately within a range from 3 nm to 12 nm. However, it will be understood that the width of the quantum wells can have values outside this range depending on the desired wavelength of light emission. Further, it will be understood that light emitting region 16 can include one or more active regions 10 and the use of three active regions in this embodiment is for illustrative purposes only.

Cladding region 14 is approximately 2 nm thick and includes p-type doped aluminum gallium arsenide (AlₓGaₗ₋ₓAs), wherein x is a number within a range from zero to one. In this specific example, x is approximately equal to 0.65 and the doping concentration is approximately 5×10¹⁷ cm⁻³. Further, it is well known by those skilled in the art that beryllium (Be) is generally used to achieve p-type doping in aluminum gallium arsenide (AlₓGaₗ₋ₓAs) layers but that other doping elements could be used, if desired.

Cladding region 22 is approximately 2 nm thick and includes n-type doped aluminum gallium arsenide (AlₓGaₗ₋ₓAs), wherein x is a number within a range from zero to one. In this specific example, x is approximately equal to 0.65 and the doping concentration is approximately 5×10¹⁷ cm⁻³. Further, it is well known by those skilled in the art that silicon (Si) is generally used to achieve n-type doping in aluminum gallium arsenide layers (AlₓGaₗ₋ₓAs) 15 but that other doping elements could be used, if desired. Further, it will be understood that region 14 is illustrated as being p-type doped and region 22 is illustrated as being n-type doped for'simplicity and ease of discussion but that other doping configurations are possible, if desired.

Capping layer 24 includes n⁺ doped gallium arsenide (GaAs) and at least one of its purposes is to minimize unintentional oxidation of semiconductor laser device 5. Capping layer 24 also provides good electrical contact for external communication. It will be understood, however, that capping layer 24 is optional and can include other material layers well known by those skilled in the art. Further, the conductivity type of capping layer 24 is typically the same conductivity type as cladding region 22, which in this example is n-type.

It will be understood that, while cladding regions 14 and 22 are illustrated as single layers, they may include more complicated structures, such as distributed Bragg reflectors consisting of alternating GaAs/AlₓGaₗ₋ₓAs layer pairs used in surface light emitting, for example vertical cavity surface emitting lasers (VCSELs) and resonant cavity light emitting diodes (RCLEDs), or resonant cavity photodetectors (RCPDs), or other light detecting devices. However, in the preferred embodiment, cladding regions 14 and 22 are illustrated as including a single material layer for simplicity and ease of discussion.

The method of fabricating semiconductor device 5 includes using a surfactant, such as antimony (Sb), to improve the morphology and electrical properties of the material layers included therein. It will be understood, however, that surfactants such as indium (In), bismuth (Bi), thallium (Tl), or the like, could also or alternatively be used to improve the morphology and the use of antimony (Sb) in this embodiment is for illustrative purposes only. As an example, various Sb/(Ga+Al) flux ratios, e.g. 0.0, 0.005, 0.01, and 0.02 are used during the deposition of the aluminum gallium arsenide (AlₓGaₗ₋ₓAs) layers (e.g. cladding regions 14 and 22) to illustrate the effects of using antimony (Sb) as the surfactant on the optoelectronic properties of the device.

Here the flux ratio is defined as the ratio of the number of surfactant (e.g. antimony) atoms deposited per unit area per unit time to the number of the sum of the semiconductor material (e.g. aluminum, gallium, etc.) atoms deposited per unit area per unit time. A general term for the flux ratio can be, for example, surfactant atoms/semiconductor atoms. It will be understood, that the method of fabrication can be used with other material systems, such as indium aluminum arsenide (InAlAs), aluminum gallium arsenic phosphide (AlₓGaₗ₋ₓAs_{y}P_{l-y}) or other semiconductor material systems well known by those. skilled in the art.

In this embodiment, the antimony (Sb) flux is supplied from a solid source valved cracker in an MBE system. Further, the Sb/(Ga+Al) flux ratio is in a range approximately from 0.0025 to 0.05 depending on the growth temperature. In this illustration, the growth temperature of the aluminum gallium arsenide (AlₓGaₗ₋ₓAs) layers is within a range approximately from 525° C. to 750° C., but it will be understood that other temperatures outside this range may be appropriate. It will be understood by one skilled in the art that growth of AlxGal-xAs in the temperature range between 620 and 700° C. is typically very difficult, and growth in this temperature range produces materials with inferior surface morphologies, electronic and optical properties. It will also be understood that other Sb/(Ga+Al) flux ratios can also be used.

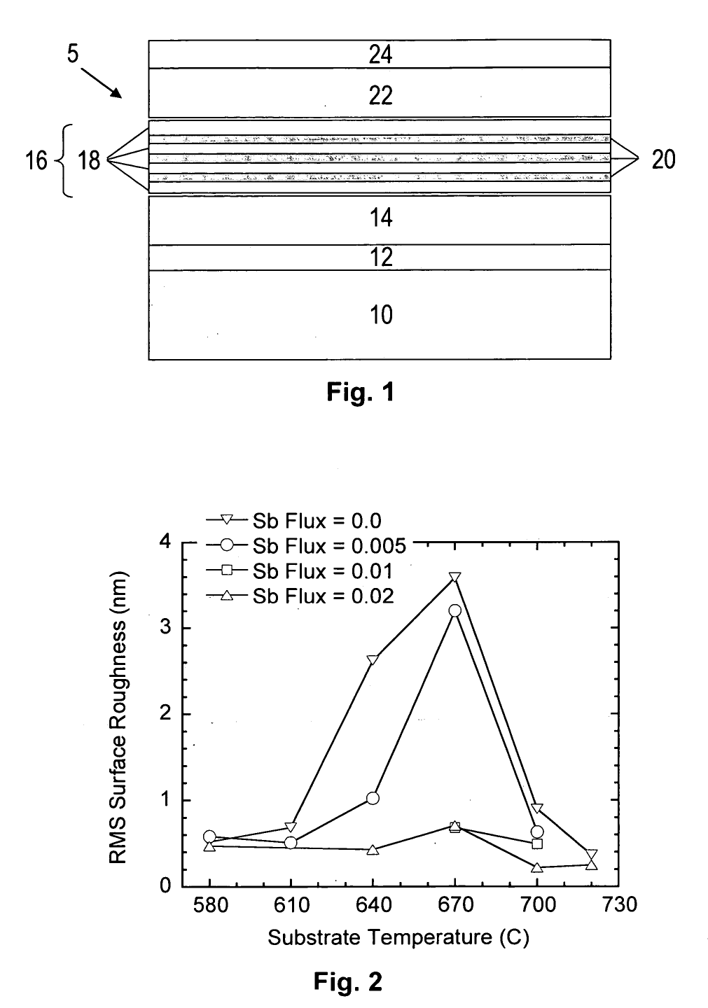

Turn now to FIG. 2 which illustrates a graph of atomic force microscopy results (hereinafter referred to as “AFM”) of various Sb/(Ga+Al) flux ratios (i.e. 0, 0.005, 0.01, and 0.02). It is well know by those skilled in the art that AFM is used to measure a root mean square (RMS) surface roughness of a material layer. Hence, the graph in FIG. 2 is a plot of the RMS surface roughness measured in nanometers verses a substrate temperature (in a range from approximately 580° C. to approximately 700° C.) at which the material layer is deposited.

As illustrated in FIG. 2, the RMS surface roughness without antimony (Sb) (i.e. Sb/(Ga+Al)=0.0) increases with temperature. This corresponds to the optimal growth conditions for antimony (Sb) free, aluminum gallium arsenide (AlₓGaₗ₋ₓAs) layers. As illustrated, the amount of antimony (Sb) flux required for smoothing (i.e. a decrease in the RMS surface roughness) increases with the substrate temperature. For example, an antimony (Sb) flux ratio of 0.005 for a substrate temperature that is less than approximately 640° C. results in an improved surface morphology. However, the antimony (Sb) flux ratio must be increased to approximately 0.01 to 0.02 for substrate temperatures greater than approximately 640° C. to obtain a suitable RMS surface roughness for device performance.

Smoothing is seen for a wide substrate temperature region (i.e. approximately from 580° C. to 720° C.). For the lowest substrate temperature, the antimony (Sb) incorporation factor is approximately unity, while for the highest temperature the antimony (Sb) incorporation factor is close to zero. Further, the smoothing effect occurs for a wide range of aluminum (Al) composition regions. In general, FIG. 2 indicates that the RMS surface roughness of the aluminum gallium arsenide (AlₓGaₗ₋ₓAs) layers decreases as the antimony (Sb) flux concentration increases and as the substrate temperature is increased. This indicates that smooth surfaces can be deposited at lower temperatures by using a non-zero antimony (Sb) flux ratio. Smoother material layers are ideal for improving optoelectronic device performance, such as reducing the light scattering from the DBR mirrors in VCSELs. Further, smoother material layers improve interface quality in devices, such as high electron mobility transistors, wherein it is desired to have a smooth interface near a conduction channel.

In another example, heterostructure bipolar transistors typically have an undesirable inhomogeneous breakdown voltage due to surface roughness; Further, the homogeneity of the electrical characteristics of resonant tunneling diodes is typically sensitive to interface quality. Hence, by fabricating optoelectronic and electronic devices with less surface roughness and smoother interfaces, the device performance and uniformity is improved.

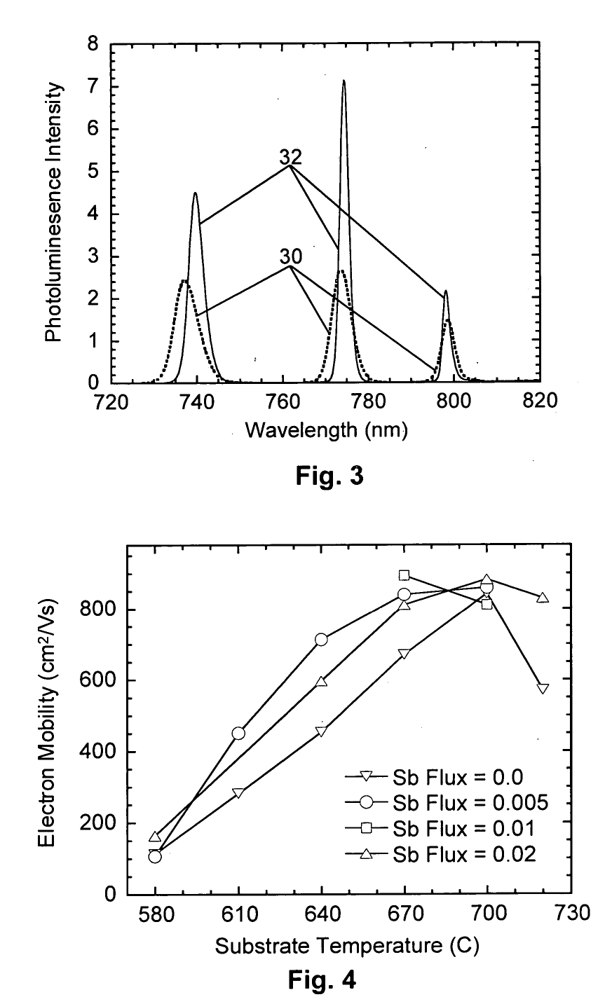

Turn now to FIG. 3 which illustrates photoluminescence graphs 30 and 32 of the gallium arsenide (GaAs) quantum wells included within active region 20 grown on top of cladding region 14, which was grown with (graph 32) and without (graph 30) the aid of an antimony (Sb) surfactant. The antimony (Sb) flux ratio during the growth of cladding region 14 was equal to approximately 0.0 and 0.01 for graphs 30 and 32, respectively. For illustrative purposes and to better demonstrate the effects of using the surfactant during the fabrication of semiconductor laser device 5, quantum wells with thicknesses of 4 nm, 6.2 nm, and 10 nm were grown so that three distinct photoluminescence peaks can be measured for each antimony (Sb) flux ratio.

It is seen in FIG. 3 that an antimony (Sb) surfactant (graph 32) improves the quality of the photoluminescence peaks wherein the photoluminescence peaks increase in intensity and become narrower as measured at a FWHM. The decrease in the intensity and increase in width of the photoluminescence peaks is generally attributed to less inhomogeneous broadening caused by fluctuations in the quantum well width, which indicates the desirability of a smoother and higher quality material layer and, therefore, less fluctuation in the quantum well width.

Turn now to FIG. 4 which illustrates electron mobility of the n-type doped aluminum gallium arsenide (AlₓGaₗ₋ₓAs) layer (e.g. region 22). It will be understood that similar results are expected for a hole mobility of the p-type doped aluminum gallium arsenide (AlₓGaₗ₋ₓAs) layer (e.g. region 14). As shown in FIG. 4, the electron mobility of n-type doped aluminum gallium arsenide (AlₓGaₗ₋ₓAs) layers grown with an antimony (Sb) flux ratio at temperatures below 700° C. increases between 20% to 50% compared to aluminum gallium arsenide (AlₓGaₗ₋ₓAs) material layers grown with an antimony (Sb) flux ratio equal to zero.

An increased electron mobility is desirable in high-speed optoelectronic devices wherein it is desirable to increase a device switching speed. Improved electron mobility also helps to reduce the electrical resistance in thick (AlxGal,As) cladding layers or DBR mirror stacks. Hence, by incorporating a surfactant during the aluminum gallium arsenide (AlₓGaₗ₋ₓAs) deposition, the optoelectronic properties of semiconductor laser device 5 are dramatically improved.

Thus, a new and improved semiconductor device and method of forming the device using a surfactant during epitaxial growth has been disclosed. The new and improved semiconductor device and method of forming the device allows deposition at temperatures that are substantially reduced thereby reducing surface roughness from prior art methods. Further, the new and improved semiconductor device and method of forming the device greatly improves carrier mobility and surface morphology.

The use of the surfactant enables a higher electron mobility and higher hole mobility, decreases surface roughness of the semiconductor material, improves the optical quality of the semiconductor material and enables growth of a compound semiconductor material with excellent surface morphology over an extended temperature range where high quality growth is not possible without the use of the surfactant.

Various changes and modifications to one or more of the embodiments herein chosen for purposes of illustration will readily occur to those skilled in the art. To the extent that such modifications and variations do not depart from the spirit of the invention, they are intended to be included within the scope thereof, which is assessed only by a fair interpretation of the following claims.

Having fully described the invention in such clear and concise terms as to enable those skilled in the art to understand and practice the same, the invention claimed is:

1. A method of fabricating a semiconductor device comprising the steps of:
depositing multiple layers of semiconductor material on a supporting substrate to form the semiconductor device; and
depositing at least one layer of the multiple layers in the presence of a surfactant.

2. The method of claim 1 wherein the surfactant is chosen from the group consisting of antimony, indium, bismuth and thallium.

3. The method of claim 1 wherein the surfactant and semiconductor material is in a flux ratio in a range of approximately from 0.0001 to 0.1.

4. The method of claim 1 wherein the semiconductor material includes aluminum and gallium.

5. The method of claim 4 wherein the surfactant includes antimony.

6. The method of claim 5 wherein the at least one layer is grown with the supporting substrate at a temperature in a range from approximately 400° C. to 800° C.

7. The method of claim 6 wherein the flux ratio is in a range of approximately 0.0001 to 0.1.

8. The method of claim 1 wherein the semiconductor device includes at least one of a high electron mobility transistor, a vertical cavity surface emitting laser, an edge emitting laser, a heterostructure bipolar transistor, a resonant tunneling diode, and the like.

9. A method of fabricating a semiconductor laser comprising the steps of:
depositing a plurality of layers of semiconductor material including at least one active area with opposed major surfaces and a cladding layer adjacent each opposed major surface; and
at least one of the active area and the cladding layers being deposited in the presence of a surfactant.

10. The method of claim 9 wherein the surfactant is chosen from the group consisting of antimony, indium, bismuth and thallium.

11. The method of claim 9 wherein the surfactant and semiconductor material is in a flux ratio in a range of approximately from 0.0001 to 0.1.

12. The method of claim 9 wherein the semiconductor material includes aluminum and gallium.

13. The method of claim 12 wherein the surfactant includes antimony.

14. The method of claim 13 wherein the at least one layer is grown with the supporting substrate at a temperature in a range from approximately 400° C. to 800° C.

15. The method of claim 14 wherein the flux ratio is in a range of approximately 0.0001 to 0.1.

16. A semiconductor device comprising:
a plurality of layers of semiconductor material epitaxially grown one on another; and
at least one of the semiconductor layers including a surfactant with the semiconductor material.

17. A semiconductor device as claimed in claim 16 wherein the surfactant is chosen from the group consisting of antimony, indium, bismuth and thallium.

18. A semiconductor device as claimed in claim 17 wherein the surfactant and semiconductor material are in a flux ratio in a range of approximately from 0.0001 to 0.1.

19. A semiconductor device as claimed in claim 16 wherein the semiconductor material includes one of aluminum and gallium.

20. A semiconductor device as claimed in claim 19 wherein the surfactant includes antimony.

21. A semiconductor device as claimed in claim 20 wherein the flux ratio is in a range of approximately 0.0001 to 0.1.

22. A semiconductor device as claimed in claim 16 wherein the semiconductor device includes at least one of a high electron mobility transistor, a vertical cavity surface emitting laser, an edge emitting laser, a heterostructure bipolar transistor, a resonant tunneling diode, and the like.
